(19) United States
(12) Patent Application Publication
(10) Pub. No.: US 2023/0392736 A1
(43) Pub. Date: Dec. 7, 2023

(54) COUPLER APPLIED TO GAS SUPPLY EQUIPMENT IN SEMICONDUCTOR MANUFACTURING PROCESS

(71) Applicant: P&C TECH CO., LTD., Hwaseong-si, Gyeonggi-do (KR)

(72) Inventor: Young Gil PARK, Hwaseong-si, Gyeonggi-do (KR)

(73) Assignee: P&C TECH CO., LTD., Hwaseong-si, Gyeonggi-do (KR)

(21) Appl. No.: 18/032,162

(22) PCT Filed: Oct. 16, 2021
(86) PCT No.: PCT/KR2021/014424

§ 371 Date: Apr. 14, 2023

(30) Foreign Application Priority Data
Oct. 16, 2020 (KR) 10-2020-0134430

(51) Int. Cl. F16L 37/23; F16L 37/56

(52) U.S. Cl. CPC F16L 37/23; F16L 37/56

(57) ABSTRACT

A coupler which connects a nipple provided on a cylinder valve of a gas supply line in a semiconductor process to an operating fluid supply line, includes: a first inlet port connected to the operating fluid supply line; a housing having a first cavity that is in communication with the first inlet port; at least one ball which is engaged with a ring-shaped engaging recess formed around a connection portion of the nipple; and a pipe portion which is installed in the first cavity and regulates a second cavity in which the connection portion of the nipple is inserted.

### TECHNICAL FIELD

The present invention relates to a coupler applied to a gas supply facility for a semiconductor manufacturing process.

### BACKGROUND ART

Conventionally, an apparatus for supplying gas that is used for a semiconductor process includes a gas cylinder containing high-pressure gas and a cylinder valve for allowing or interrupting the supply of gas from the gas cylinder to a process facility.

The cylinder valve includes an actuator configured to be operated by pneumatic pressure, and discharge of gas from the gas cylinder is allowed or interrupted by operation of the actuator. Conventionally, high-pressure air (approximately 5 bar) as a working fluid for operating the actuator is supplied through an air hose.

When a process of connecting the air hose to the cylinder valve is not accurately performed according to instructions, or when an end of the air hose is worn or damaged due to repeated connection and disconnection of the air hose for a reason such as replacement of the gas cylinder, an accident of separation of the air hose may occur. In this case, the supply of gas may be interrupted, and thus the entire semiconductor manufacturing process may be shut down, resulting in huge losses.

### DISCLOSURE

### Technical Problem

A first problem to be solved by the present invention is to provide a coupler configured to connect a nipple provided at a cylinder valve to a working fluid supply line so that the cylinder valve, which allows or interrupts supply of gas from a gas cylinder to a semiconductor process, is controlled by a working fluid.

A second problem to be solved is to provide a coupler that makes it unnecessary to separate the working fluid supply line at the time of replacement of the gas cylinder.

A third problem to solved is to provide a structure in which the nipple and the coupler are reliably locked.

### Technical Solution

The present invention relates to a coupler that connects a nipple provided at a cylinder valve of a gas supply line for a semiconductor process to a working fluid supply line.

The coupler includes a housing having a first inlet connected to the working fluid supply line and a first cavity communicating with the first inlet, at least one ball configured to be engaged with a ring-shaped engagement groove formed in a circumference of a connection portion of the nipple, a retainer mounted in the first cavity, the retainer including a pipe portion defining a second cavity into which the connection portion of the nipple is inserted, the pipe portion having at least one ball-mounting passage formed therein to allow the at least one ball to be inserted thereinto, a switching member disposed between an inner circumferential surface of the housing defining the first cavity and an outer circumferential surface of the pipe portion, the switching member being movable between a first position and a second position, and an elastic member configured to cause the switching member to return to the first position.

The at least one ball may be moved along the ball-mounting passage in accordance with change in the position of the switching member so as to be engaged with the engagement groove or to become separable from the engagement groove.

The housing may further include a second inlet connected to a control fluid supply line configured to supply a control fluid to move the switching member. The switching member may be moved from the first position to the second position by the control fluid to deform the elastic member, and may push the ball inwards at the second position so that the ball is engaged with the engagement groove.

When the supply of the control fluid through the second inlet is interrupted, the switching member may return to the first position due to the restoring force of the elastic member, and when the switching member is located at the first position, the switching member may provide a gap to allow the ball to be moved outwards along the ball-mounting passage and thus to be separable from the engagement groove.

The housing may further include a second inlet connected to a control fluid supply line configured to supply a control fluid to move the switching member. When the control fluid is not supplied through the second inlet, the switching member may be located at the first position and may push the ball inwards so that the ball is engaged with the engagement groove, and when the control fluid is introduced through the second inlet, the switching member may be moved to the second position to provide a gap to allow the ball to be moved outwards along the ball-mounting passage and thus to be separable from the engagement groove.

The housing may further include a first flow path configured to guide a portion of a fluid introduced through the first inlet to the second cavity and a second flow path branched from the first flow path to guide the remaining portion of the introduced fluid to the switching member.

The coupler may further include a manipulation rod, which is connected to the switching member and has one end exposed to the outside of the housing.

When the switching member is located at the first position, the switching member may push the ball inwards so that the ball is engaged with the engagement groove, and when the switching member is located at the second position, the switching member may provide a gap to allow the ball to be moved outwards along the ball-mounting passage and thus to be separable from the engagement groove.

The switching member may have an inner surface formed to be in contact with the ball, the inner surface including a small-diameter portion having a first inner diameter, a large-diameter portion having a second inner diameter larger than the first inner diameter, and an inclined portion interconnecting the small-diameter portion and the large-diameter portion. The ball may be in contact with the inclined portion while the switching member moves between the first position and the second position.

The ball-mounting passage may include an inner opening located in an inner circumferential surface of the pipe portion, the inner opening being smaller than the diameter of the ball, and an outer opening located in an outer circumferential surface of the pipe portion, the outer opening being larger than the inner opening.

According to another aspect of the present invention, a flow path connection mechanism, which connects a cylinder valve of a gas supply line for a semiconductor process to a working fluid supply line, includes a nipple connected to the cylinder valve and a coupler connected to the working fluid supply line and detachably coupled to the nipple, wherein the coupler includes a housing having a first inlet connected to the working fluid supply line and a first cavity communicating with the first inlet, wherein the nipple includes a connection portion inserted into the first cavity, the connection portion having a ring-shaped engagement groove formed in a circumference thereof, wherein the coupler further includes at least one ball configured to be engaged with the ring-shaped engagement groove, a retainer mounted in the first cavity, the retainer including a pipe portion defining a second cavity into which the connection portion of the nipple is inserted, the pipe portion having at least one ball-mounting passage formed therein to allow the at least one ball to be inserted thereinto, a switching member disposed between an inner circumferential surface of the housing defining the first cavity and an outer circumferential surface of the pipe portion, the switching member being movable between a first position and a second position, and an elastic member configured to cause the switching member to return to the first position, and wherein the at least one ball is moved along the ball-mounting passage in accordance with change in the position of the switching member so as to be engaged with the engagement groove or to become separable from the engagement groove.

### Advantageous Effects

According to the present invention, it is possible to replace a gas cylinder in a manner of connecting or disconnecting a nipple connected to the gas cylinder to or from a coupler in the state in which connection of the coupler to a working fluid supply line is maintained. Therefore, even when replacement of the gas cylinder is repeated, there is no possibility of a connection portion of the working fluid supply line becoming worn or deformed, and it is possible to prevent losses due to human error and shutdown of a semiconductor process, which occur in a conventional method of manually separating and re-connecting the working fluid supply line.

In addition, since connection of a gas supply facility necessary for a semiconductor manufacturing process is automatically achieved through supply of a working fluid, an unmanned automated process is realized.

### DESCRIPTION OF DRAWINGS

FIG. 1 is a view schematically showing a gas supply facility for a semiconductor process according to an embodiment of the present invention.

FIG. 2 shows a coupler according to a first embodiment of the present invention, where (a) is a front view of the coupler, and (b) is a plan view of the coupler.

FIG. 3 shows the longitudinal-section of the coupler shown in FIG. 2, where (a) shows an unlocked state of the coupler before injection of air, and (b) shows a locked state of the coupler after injection of air.

FIG. 4 shows the longitudinal-section of a coupler according to a second embodiment of the present invention, where (a) shows a locked state of the coupler before injection of air, and (b) shows an unlocked state of the coupler after injection of air.

FIG. 5 shows a coupler according to a third embodiment of the present invention, where (a) is a front view of the coupler, and (b) is a plan view of the coupler.

FIG. 6 shows the longitudinal-section of the coupler shown in FIG. 5, where (a) shows an unlocked state of the coupler before injection of air, and (b) shows a locked state of the coupler after injection of air.

FIG. 7 shows a coupler according to a fourth embodiment of the present invention, where (a) is a front view of the coupler, and (b) is a plan view of the coupler.

FIG. 8 shows the longitudinal-section of the coupler shown in FIG. 7, where (a) shows a locked state of the coupler when a manipulation rod is located at a locking position, and (b) shows an unlocked state of the coupler when the manipulation rod is located at an unlocking position.

### BEST MODE

Advantages and features of the present invention and methods for achieving them will be made clear from embodiments described below in detail with reference to the accompanying drawings. The present invention may, however, be embodied in many different forms, and should not be construed as being limited to the embodiments set forth herein. Rather, these embodiments are provided so that this disclosure will be thorough and complete, and will fully convey the scope of the invention to those skilled in the art. The present invention is defined only by the scope of the claims. The same reference numerals used throughout the specification refer to the same constituent elements.

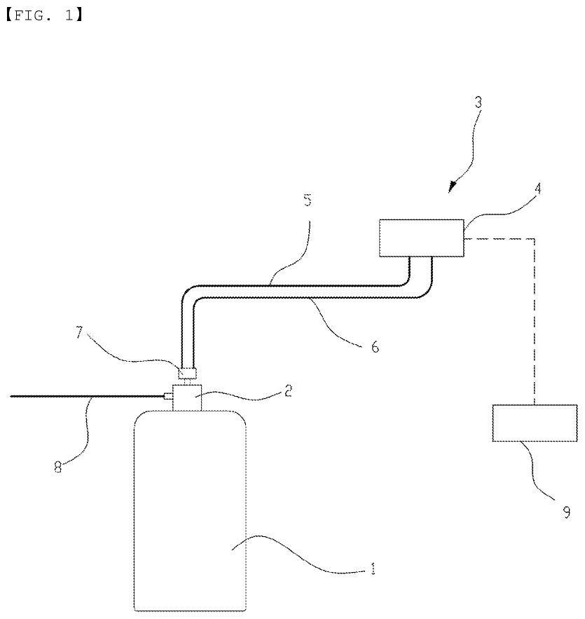

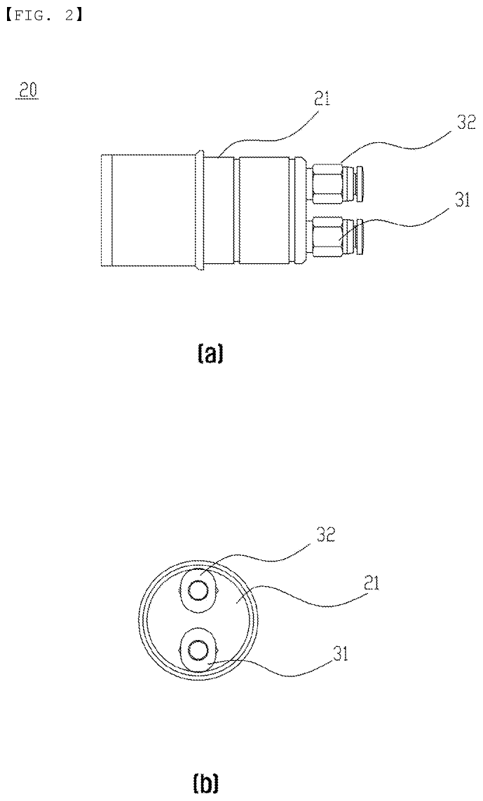

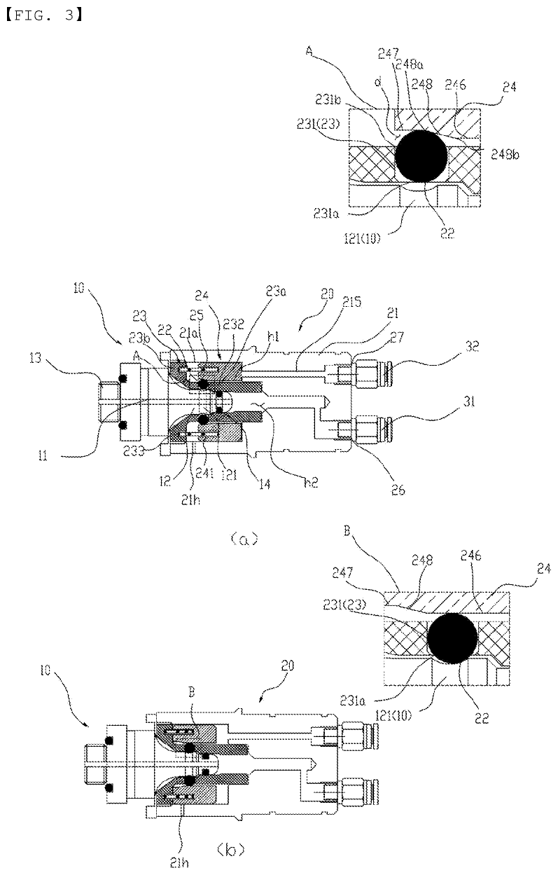

FIG. 1 is a view schematically showing a gas supply facility for a semiconductor process according to an embodiment of the present invention. FIG. 2 shows a coupler according to a first embodiment of the present invention, where (a) is a front view of the coupler, and (b) is a plan view of the coupler. FIG. 3 shows the longitudinal-section of the coupler shown in FIG. 2, where (a) shows an unlocked state of the coupler before injection of air, and (b) shows a locked state of the coupler after injection of air.

Referring to FIG. 1, a gas supply facility according to an embodiment of the present invention is provided to supply gas necessary for a semiconductor process, and may include a gas cylinder 1 configured to contain gas, a hydraulically-actuated cylinder valve 2 configured to allow or interrupt discharge of gas from the gas cylinder 1, and a valve control device 3 configured to supply a fluid (hereafter referred to as a “working fluid”) to the cylinder valve 2 to control operation of the cylinder valve 2. The following description will be given on the assumption that the working fluid is air and the cylinder valve 2 is a pneumatic valve configured to be opened and closed by pneumatic pressure, but the disclosure is not necessarily limited thereto.

The valve control device 3 may include a fluid supply 4 configured to discharge compressed air, a working fluid supply line 5 and a control fluid supply line 6 configured to individually guide air discharged from the fluid supply 4, a flow path connection mechanism 7 configured to connect the working fluid supply line 5 to the cylinder valve 2, and a controller 9 configured to control the fluid supply 4.

The controller 9 may control the fluid supply 4 such that air is discharged to the working fluid supply line 5 and the control fluid supply line 6 simultaneously or selectively. When the air supplied from the working fluid supply line 5 is supplied to the cylinder valve 2 through the flow path connection mechanism 7, the cylinder valve 2 is opened by pneumatic pressure, whereby gas in the gas cylinder 1 is discharged to the gas supply line 8 and then is supplied to various facilities for the semiconductor process.

The flow path connection mechanism 7 includes a nipple 10 connected to the cylinder valve 2 and a coupler 20 connected to the working fluid supply line 5 and detachably coupled to the nipple 10.

The coupler 20 may be connected to the working fluid supply line 5. In the state in which the coupler 20 is coupled to the nipple 10, the air supplied by the working fluid supply line 5 is supplied to the cylinder valve 2 through the nipple 10, thereby opening the cylinder valve 2.

While the working fluid (e.g. air) is supplied to the cylinder valve 2, the coupler 20 should not be separated from the nipple 10. The coupler 20 according to the embodiment maintains or releases a connection state between the coupler 20 and the nipple 10 (i.e. is locked or unlocked) using a control fluid (e.g. air) introduced through the control fluid supply line 6.

Referring to FIGS. 2 and 3, the coupler 20 includes a housing 21, at least one ball 22, a retainer 23, a switching member 24, and an elastic member 25.

The housing 21 may have formed therein a first inlet 26 connected to the working fluid supply line 5 and a first cavity h1 communicating with the first inlet 26. The first inlet 26 and a second inlet 27 may be directly connected to the fluid supply lines 5 and 6, but it is preferable that the first inlet 26 and the second inlet 27 be respectively connected to the fluid supply lines 5 and 6 via a first inlet port 31 and a second inlet port 32.

The nipple 10 is formed as a hollow body having a flow path 11 formed therein to guide the fluid to be supplied to the cylinder valve 2. The nipple 10 includes a connection portion 12 formed at one end thereof to be connected to the coupler 20 and a connection port 13 formed at the other end thereof to be connected to the cylinder valve 2. The connection portion 12 may have a ring-shaped engagement groove 121, which is formed in the outer circumferential surface of the connection portion 12 and extends in a circumferential direction. The connection portion 12 may be provided with an O-ring 14 to seal a gap between the connection portion 12 and a pipe portion 23a of the retainer 23.

The retainer 23 may be mounted in the first cavity h1 in the housing 21. The retainer 23 may include a pipe portion 23a defining a second cavity h2 into which the connection portion 12 of the nipple 10 is inserted. At least one ball-mounting passage 231, into which the at least one ball 22 is inserted, may be formed in the pipe portion 23a. A plurality of ball-mounting passages 231 may be formed in the circumferential direction. Preferably, the plurality of ball-mounting passages 231 may be disposed at regular angles in the circumferential direction, so that a plurality of balls 22 may be simultaneously engaged with the ball-mounting passages 231 according to operation of the switching member 24, which will be described later.

The switching member 24 may be disposed in a space between an inner circumferential surface 21a of the housing 10, which defines the first cavity h1, and an outer circumferential surface 232 of the pipe portion 23a (hereinafter referred to as a mounting space). The switching member 24 is movable between a first position (a position shown in FIG. 3(a)) and a second position (a position shown in FIG. 3(b)). Hereinafter, the “first position” is defined as a position of the switching member 24 when the elastic member 25 is maintained in the original shape thereof before being deformed, and the “second position” is defined as a position of the switching member 24 in a state of deforming (or compressing) the elastic member 25.

The elastic member 25 causes the switching member 24 to return from the second position (refer to FIG. 3(b)) to the first position (refer to FIG. 3(a)). As the switching member 24 is moved from the first position to the second position by the pneumatic pressure applied thereto through the second inlet 27, the elastic member 25 is deformed or displaced. Therefore, when the supply of air through the second inlet 27 is interrupted and thus the pneumatic pressure is removed, the switching member 24 returns from the second position to the first position due to the restoring force of the elastic member 25. Here, the elastic member 25 may be a compression spring.

The retainer 23 may further include a cap portion 23b, which expands radially outwards from one end of the pipe portion 23a to close one surface of the first cavity h1. A first fixing groove 233, into which one end of the elastic member 25 or the spring is inserted, may be formed in the bottom surface of the cap portion 23b. A second fixing groove 241, into which the other end of the elastic member 25 is inserted, may be formed in one surface of the switching member 24.

The housing 21 may have at least one air ventilation hole 21h formed therein to allow the mounting space to communicate with the outside of the housing 21. While the space is expanded and contracted by movement of the switching member 24, air may be introduced into or discharged out of the housing 21 through the air ventilation hole 21h.

The ball 22 is provided to be movable along the ball-mounting passage 231. The ball 22 is at least partially located in the ball-mounting passage 231, and is moved in accordance with change in the position of the switching member 24 so as to be engaged with the engagement groove 121 or to become separable from the engagement groove 121.

The ball-mounting passage 231 is a cavity that extends from an inner opening 231a located in the inner circumferential surface of the pipe portion 23a to an outer opening 231b located in the outer circumferential surface of the pipe portion 23a. At least a portion of the ball 22 may be inserted into the ball-mounting passage 231 through the outer opening 231b. The inner opening 231a is smaller than the outer opening 231b, preferably smaller than the diameter of the ball 22, thereby preventing the ball 22 from falling into the second cavity h2 through the inner opening 231a. Meanwhile, the outer opening 231b may be larger than the diameter of the ball 22 so that the ball 22 is capable of being inserted into the ball-mounting passage 231.

In the state in which the ball 22 is pushed inwards along the ball-mounting passage 231 by the switching member 24, at least a portion of the ball 22 is exposed to the interior of the second cavity h2 through the inner opening 231a, and the exposed portion is engaged with the engagement groove 121 in the nipple 10, whereby the nipple 10 and the coupler 20 are locked.

That is, in the state in which the connection portion 12 of the nipple 10 is held in place in the second cavity h2, when the control fluid (air) is supplied to the control fluid supply line 6 and then is introduced into the second inlet 27 under the control of the controller 9, the introduced air is guided to the mounting space through a flow path 215 to move the switching member 24 to the second position, whereby the nipple 10 and the coupler 20 are locked. In this state, since connection between the nipple 10 and the coupler 20 is reliably ensured, the air supplied through the working fluid supply line 5 is accurately transferred to the cylinder valve 2, and accidents or process shutdown due to separation of the nipple 10 and the coupler 20 from each other is prevented.

Meanwhile, when the switching member 24 is located at the first position, the switching member 24 provides a gap to allow the ball 22 to reach a position at which the ball 22 is separable from the engagement groove 121 (hereinafter referred to as an “escape gap”). That is, in the state in which the external force applied to the ball 22 by the switching member 24 is removed, the escape gap d provides a space in which the ball 22 is capable of further moving in the outward direction of the ball-mounting passage 231 so as to completely escape from the engagement groove 121.

The inner surface of the switching member 24 that is in contact with the ball 22 may include a small-diameter portion 246 having a first inner diameter, a large-diameter portion 247 having a second inner diameter larger than the first inner diameter, and an inclined portion 248 interconnecting the small-diameter portion 246 and the large-diameter portion 247. The inclined portion 248 may be a funnel-shaped surface formed such that one end portion 248a thereof is located radially farther outward than the other end portion 248b thereof. The inclined portion 248 expands from the other end portion 248b thereof, which is narrow, to the end portion 248a thereof, which is broad. The ball 22 may pass through the inclined portion 248 while the switching member 24 moves between the first position and the second position.

In more detail, in the embodiment, when the switching member 24 is located at the first position (refer to FIG. 3(a)), the large-diameter portion 247 is located at a position corresponding to the ball 22, and the escape gap d is provided between the large-diameter portion 247 and the pipe portion 23a.

When the switching member 24 is moved to the second position (refer to FIG. 3(b)), the ball 22 is pushed and moved toward the inner opening 231a in the ball-mounting passage 231 due to the inclined portion 248, and finally is brought into contact with the large-diameter portion 247.

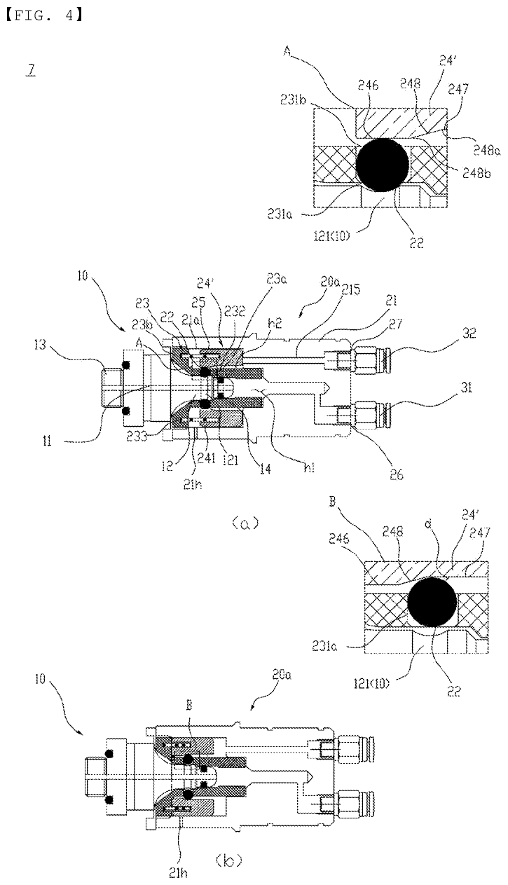

FIG. 4 shows the longitudinal-section of a coupler according to a second embodiment of the present invention, where (a) shows a locked state of the coupler before injection of air, and (b) shows an unlocked state of the coupler after injection of air.

Referring to FIG. 4, in contrast to the first embodiment described above, a coupler 20a according to the second embodiment of the present invention is locked when a switching member 24′ is located at a first position (refer to FIG. 4(a)), and is unlocked when the switching member 24′ is located at a second position (refer to FIG. 4(b)). The positions of a large-diameter portion 247 and a small-diameter portion 246 are opposite to those in the first embodiment, and accordingly, the expansion direction of an inclined portion 248′ is opposite to that in the first embodiment.

In detail, when the control fluid is not supplied through the second inlet 27, the switching member 24′ is located at the first position and pushes the ball 22 inwards so that the ball 22 is engaged with the engagement groove 121, and when the control fluid is introduced through the second inlet 27, the switching member 24′ is moved to the second position to provide a gap to allow the ball 22 to be moved outwards along the ball-mounting passage 231 and thus to be separable from the engagement groove 121.

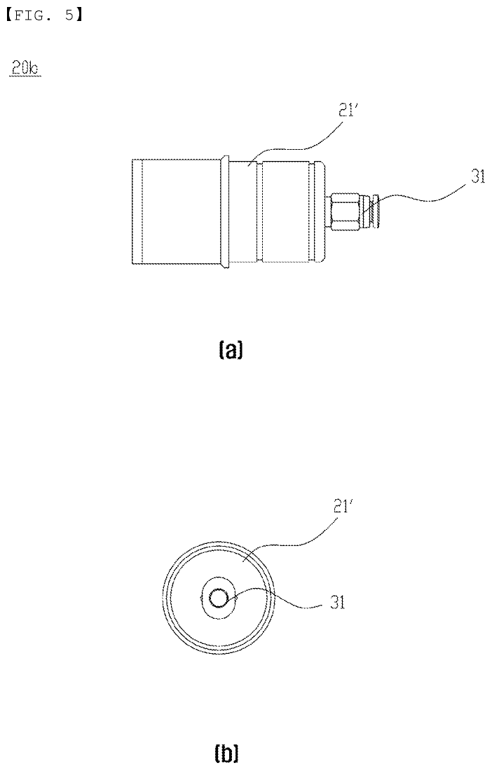

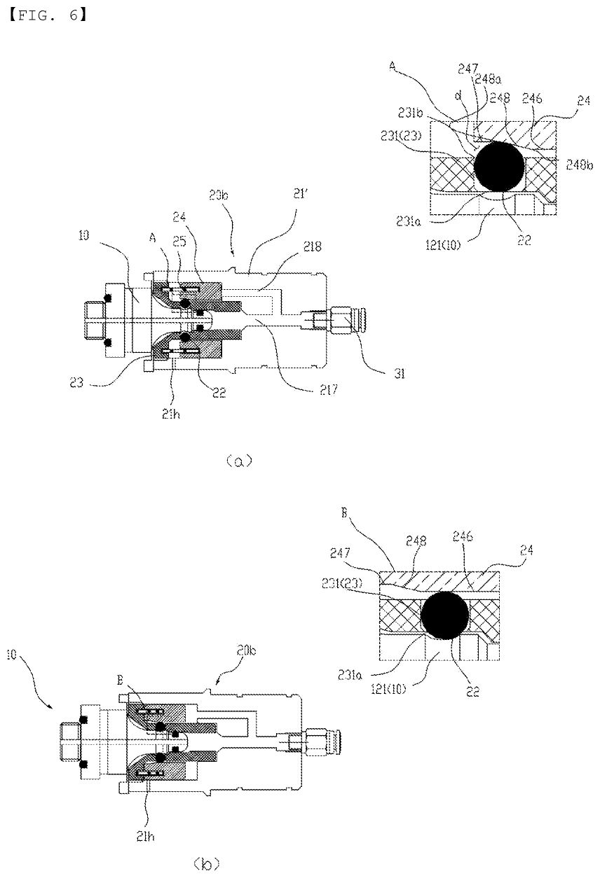

FIG. 5 shows a coupler according to a third embodiment of the present invention, where (a) is a front view of the coupler, and (b) is a plan view of the coupler. FIG. 6 shows the longitudinal-section of the coupler shown in FIG. 5, where (a) shows an unlocked state of the coupler before injection of air, and (b) shows a locked state of the coupler after injection of air.

Referring to FIGS. 5 and 6, a coupler 20b according to the third embodiment of the present invention is configured such that the second inlet 27 in each of the above-described embodiments is eliminated therefrom and such that not only operation of the cylinder valve 2 but also locking operation of the switching member 24 are performed by the fluid introduced through the first inlet 26. That is, opening of the cylinder valve 2 and locking of the flow path connection mechanism 7 are realized at the same time due only to supply of the fluid through the working fluid supply line 5.

In detail, according to this embodiment, the housing 21′ may include a first flow path 217, which guides a portion of the fluid introduced through the first inlet 26 to the second cavity h2, and a second flow path 218, which is branched from the first flow path 217 to guide the remaining portion of the introduced fluid to the switching member 24. The switching member 24 is moved by the fluid supplied through the second flow path 218.

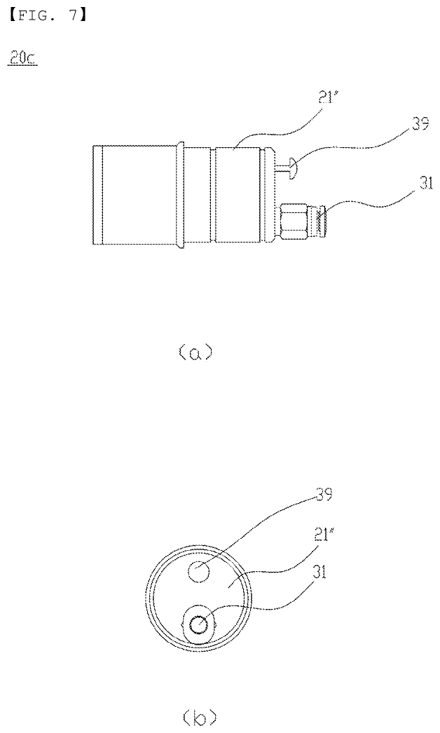

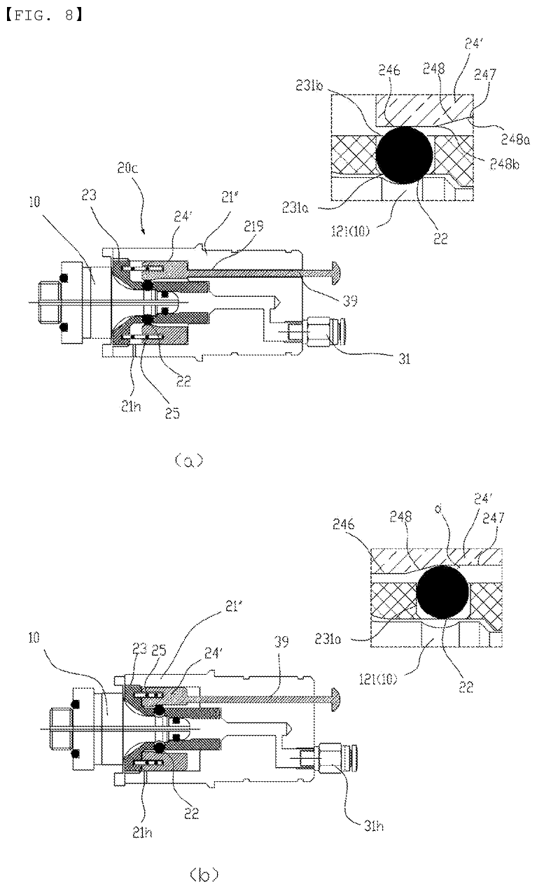

FIG. 7 shows a coupler according to a fourth embodiment of the present invention, where (a) is a front view of the coupler, and (b) is a plan view of the coupler. FIG. 8 shows the longitudinal-section of the coupler shown in FIG. 7, where (a) shows a locked state of the coupler when a manipulation rod is located at a locking position, and (b) shows an unlocked state of the coupler when the manipulation rod is located at an unlocking position.

Referring to FIGS. 7 and 8, a coupler 20c according to the fourth embodiment of the present invention is configured such that a switching member 24′ is moved by operation of pushing or pulling a manipulation rod 39. The manipulation rod 39 may be pushed or pulled by manual power or by mechanical power of a separate device.

The manipulation rod 39 may be connected to the switching member 24′, and one end thereof may be exposed to the outside of a housing 21″. The manipulation rod 39 may be integrally formed with the switching member 24′, or may be provided separately from the switching member 24′ to be coupled to the switching member 24′ in order to facilitate assembly with the housing 21″. The housing 21″ may have a hole 219 formed therein to allow the manipulation rod 39 to be inserted thereinto.

When the switching member 24′ is located at the first position (refer to FIG. 8(a)), the switching member 24′ pushes the ball 22 inwards so that the ball 22 is engaged with the engagement groove 121, and when the switching member 24′ is located at the second position (refer to FIG. 8(b)), the switching member 24′ provides a gap to allow the ball 22 to be moved outwards along the ball-mounting passage 231 and thus to be separable from the engagement groove 121.

1. A coupler connecting a nipple provided at a cylinder valve of a gas supply line for a semiconductor process to a working fluid supply line, the coupler comprising:
a housing having a first inlet connected to the working fluid supply line and a first cavity communicating with the first inlet;
at least one ball configured to be engaged with a ring-shaped engagement groove formed in a circumference of a connection portion of the nipple;
a retainer mounted in the first cavity, the retainer comprising a pipe portion defining a second cavity into which the connection portion of the nipple is inserted, the pipe portion having at least one ball-mounting passage formed therein to allow the at least one ball to be inserted thereinto;
a switching member disposed between an inner circumferential surface of the housing defining the first cavity and an outer circumferential surface of the pipe portion, the switching member being movable between a first position and a second position; and
an elastic member configured to cause the switching member to return to the first position,
wherein the at least one ball is moved along the ball-mounting passage in accordance with change in position of the switching member so as to be engaged with the engagement groove or to become separable from the engagement groove.

2. The coupler according to claim 1, wherein the housing further comprises a second inlet connected to a control fluid supply line configured to supply a control fluid to move the switching member, and
wherein the switching member is moved from the first position to the second position by the control fluid to deform the elastic member, and pushes the ball inwards at the second position so that the ball is engaged with the engagement groove.

3. The coupler according to claim 2, wherein, when supply of the control fluid through the second inlet is interrupted, the switching member returns to the first position due to a restoring force of the elastic member, and when the switching member is located at the first position, the switching member provides a gap to allow the ball to be moved outwards along the ball-mounting passage and to be separable from the engagement groove.

4. The coupler according to claim 1, wherein the housing further comprises a second inlet connected to a control fluid supply line configured to supply a control fluid to move the switching member, and
wherein, when the control fluid is not supplied through the second inlet, the switching member is located at the first position and pushes the ball inwards so that the ball is engaged with the engagement groove, and when the control fluid is introduced through the second inlet, the switching member is moved to the second position to provide a gap to allow the ball to be moved outwards along the ball-mounting passage and to be separable from the engagement groove.

5. The coupler according to claim 1, wherein the housing further comprises a first flow path configured to guide a portion of a fluid introduced through the first inlet to the second cavity and a second flow path branched from the first flow path to guide a remaining portion of the introduced fluid to the switching member.

6. The coupler according to claim 1, further comprising:
a manipulation rod connected to the switching member, the manipulation rod having one end exposed to an outside of the housing.

7. The coupler according to claim 6, wherein, when the switching member is located at the first position, the switching member pushes the ball inwards so that the ball is engaged with the engagement groove, and when the switching member is located at the second position, the switching member provides a gap to allow the ball to be moved outwards along the ball-mounting passage and to be separable from the engagement groove.

8. The coupler according to claim 1, wherein the switching member has an inner surface formed to be in contact with the ball, the inner surface comprising a small-diameter portion having a first inner diameter, a large-diameter portion having a second inner diameter larger than the first inner diameter, and an inclined portion interconnecting the small-diameter portion and the large-diameter portion, and
wherein the ball is in contact with the inclined portion while the switching member moves between the first position and the second position.

9. The coupler according to claim 1, wherein the ball-mounting passage comprises an inner opening located in an inner circumferential surface of the pipe portion, the inner opening being smaller than a diameter of the ball, and an outer opening located in an outer circumferential surface of the pipe portion, the outer opening being larger than the inner opening.

10. A flow path connection mechanism connecting a cylinder valve of a gas supply line for a semiconductor process to a working fluid supply line, the flow path connection mechanism comprising:
a nipple connected to the cylinder valve; and
a coupler connected to the working fluid supply line and detachably coupled to the nipple,
wherein the coupler comprises a housing having a first inlet connected to the working fluid supply line and a first cavity communicating with the first inlet,
wherein the nipple comprises a connection portion inserted into the first cavity, the connection portion having a ring-shaped engagement groove formed in a circumference thereof,
wherein the coupler further comprises:
at least one ball configured to be engaged with the ring-shaped engagement groove;
a retainer mounted in the first cavity, the retainer comprising a pipe portion defining a second cavity into which the connection portion of the nipple is inserted, the pipe portion having at least one ball-mounting passage formed therein to allow the at least one ball to be inserted thereinto;
a switching member disposed between an inner circumferential surface of the housing defining the first cavity and an outer circumferential surface of the pipe portion, the switching member being movable between a first position and a second position; and
an elastic member configured to cause the switching member to return to the first position, and
wherein the at least one ball is moved along the ball-mounting passage in accordance with change in position of the switching member so as to be engaged with the engagement groove or to become separable from the engagement groove.
